(19) United States
(12) Patent Application Publication
(10) Pub. No.: US 2024/0178098 A1
(43) Pub. Date: May 30, 2024

(54) METHOD FOR PRODUCING A METAL-CERAMIC SUBSTRATE, AND METAL-CERAMIC SUBSTRATE PRODUCED USING A METHOD OF THIS TYPE

(71) Applicant: Rogers Germany GmbH, Eschenbach (DE)

(72) Inventors: Thomas KOHL, Auerbach (DE); Bernard RETTINGER, Windischeschenbach (DE)

(21) Appl. No.: 18/283,506

(22) PCT Filed: Mar. 23, 2022
(86) PCT No.: PCT/EP2022/057595

§ 371 Date: Sep. 22, 2023

(30) Foreign Application Priority Data
Mar. 26, 2021 (DE) 10 2021 107 690.0

(51) Int. Cl. H01L 23/373; H01L 21/48

(52) U.S. Cl. CPC H01L 23/3735; H01L 21/4846

(57) ABSTRACT

A method of manufacturing a metal-ceramic substrate (1), comprising:
providing a ceramic element (30) and at least one metal layer (10), wherein the ceramic element (30) and the at least one metal layer (10) extend along a main extension plane (HSE); and
bonding the ceramic element (30) to the at least one metal layer (10) to form a metal-ceramic substrate (1), in particular by means of a direct metal bonding process, hot isostatic pressing and/or a soldering process,
   wherein a structuring, preferably for forming an isolation of metal sections (10′), and/or a recess, preferably for forming a solder stop, is realized in the at least one metal layer (10) by means of a laser process and a chemical process, in particular an etching process.

### CROSS REFERENCE TO RELATED APPLICATIONS

This application is a National Stage application of PCT/EP2022/057595, filed Mar. 23, 2022, which claims the benefit of German Application No. 10 2021 107 690.0, filed Mar. 26, 2021, both of which are incorporated by reference in their entirety herein.

### BACKGROUND

The present invention relates to a method for producing a metal-ceramic substrate and to a metal-ceramic substrate produced by such a method.

Carrier substrates for electrical components, for example in the form of metal-ceramic substrates, are sufficiently known from the prior art, for example as printed circuit boards or circuit boards, for example from DE 10 2013 104 739 A1, DE 19 927 046 B4 and DE 10 2009 033 029 A1. Typically, connection areas for electrical components and conducting paths are arranged on one component side of the metal-ceramic substrate, wherein the electrical components and conducting paths can be interconnected to form electrical circuits. Essential components of the metal-ceramic substrates are an insulating layer, which is preferably manufactured from a ceramic, and a metal layer or structural metallization bonded to the insulating layer. Because of their comparatively high insulating strengths, insulating layers manufactured from ceramics have proved particularly advantageous in the field of power electronics. Conducting paths and/or connection areas for the electrical components can then be realized by structuring the metal layer.

For such carrier substrates, in particular for metal-ceramic substrates, due to the different material selection for the insulating layer on the one hand and the metallization on the other hand, there is the problem that due to different thermal expansion coefficients, thermomechanical stresses can be induced or caused in the event of heat generation, which can occur, for example, during operation or during the manufacture of the carrier substrate, which can lead to bending or even damage to the carrier substrate.

The state of the art usually provides for an etching process to be used for structuring or profiling the at least one metal layer. For this purpose, a masking, in particular in the form of a resist layer, is applied to a side of the metal layer facing away from the ceramic element. An etching agent is then used to expose those areas which have remained free of the masking, allowing structuring in the metal layer corresponding to the masking. However, such an approach is material- and time-intensive, especially with regard to the application of the masking and the use of an etching agent.

Based on this, the present invention makes it its task to reduce the amount of time and/or material required in the production of metal-ceramic substrates, in particular in their structuring.

### SUMMARY

This task is solved by a method as described herein and a metal-ceramic substrate as described herein. Further developments and further embodiments can be found in the dependent claims, the description and the figures.

According to a first aspect of the present invention, a method of manufacturing a metal-ceramic substrate, is provided, comprising:
providing a ceramic element and at least one metal layer, wherein the ceramic element and the at least one metal layer extend along a main extension plane, and
bonding the ceramic element to the at least one metal layer to form a metal-ceramic substrate, in particular by means of a direct metal bonding process, hot isostatic pressing and/or a soldering process,
   wherein structuring, preferably for forming an isolation of metal sections, and/or a recess, preferably for forming a solder stop, is realized in the at least one metal layer by means of a laser process and a chemical process, in particular etching.

### BRIEF DESCRIPTION OF THE DRAWINGS

Further advantages and features will be apparent from the following description of more preferably embodiments of the subject matter of the invention with reference to the accompanying figures. Individual features of the individual embodiment can thereby be combined with each other within the scope of the invention, wherein in the figures:

FIG. 1: a metal-ceramic substrate according to a first preferred embodiment of the present invention;

FIG. 2: a metal-ceramic substrate according to a second preferred embodiment of the present invention; and

FIG. 3: a metal-ceramic substrate according to a third preferred embodiment of the present invention.

### DETAILED DESCRIPTION

In contrast to the prior art, the invention provides not only for the use of an etching agent for structuring, but also for the use of laser light to cause a removal of material which serves to form the structuring and/or the recess. By combining these two methods, it is advantageously possible to dispense with the formation of masking. In particular, it is intended that the laser light is used to define the course of the structuring, while, for example, the etching agent used is used for uniform removal of material of the at least one metal layer. Since the laser light provides the specifications in which areas an increased removal of material takes place, the specification by masking is therefore no longer necessary, wherein the production of the structuring is accelerated and the material requirement is reduced, since, for example, no material is required for the formation of a masking.

It is conceivable that the production or removal by means of laser light and/or by means of etching agents is carried out simultaneously, at least intermittently. That is, the two independent methods for removing material can overlap in time to further accelerate the manufacturing process. For example, it is conceivable that after a fixed number of passes with the laser light, an etching agent is applied over the entire area of the at least one metal layer, while the laser light ensures further removal in further passes. More preferably, the treating with the laser light and the chemical treatment are carried out in succession.

Another advantage resulting from the combination of etching and removal with laser light is to ensure that none of the material of the ceramic element is removed during treating with the laser light. This makes it possible to avoid damage to the ceramic element by the laser light. To this end, it is particularly intended that the removal with the etching agent is not completed before the structuring with the laser light has been finished. In particular, the removal with the laser light within the scope of a preparatory or preparation step serves to specify a course of the isolation grooves and/or the recesses, which in turn obtain their final or concluding depth only through the etching step.

Preferably, at least 50%, more preferably at least 75%, and most preferably at least 90% of the removal of material is carried out by means of laser light.

In particular, recesses are understood to be those profiles in the at least one metal layer which do not lead to an isolation of two adjacent metal sections but serve, for example, to be used as a solder stop. Such a solder stop prevents, for example, unwanted flow of the solder material into certain areas by the recess acting as a groove to receive the solder material and thus prevent it from flowing further.

As materials for the at least one metal layer or the backside metallization in the metal-ceramic substrate, copper, aluminum, molybdenum and/or alloys thereof, as well as laminates such as CuW, CuMo, CuAl, AlCu and/or CuCu are conceivable, in particular a copper sandwich structure with a first copper layer and a second copper layer, wherein a grain size in the first copper layer differs from the grain size in a second copper layer. Furthermore, it is preferably provided that the primary metal layer is surface-modified, in particular as structural metallization. Conceivable surface modifications include, for example, sealing with a precious metal, in particular silver and/or gold, or ENIG (“electroless nickel immersion gold”), nickel or edge encapsulation on the at least one metal layer to suppress crack formation or expansion.

Preferably, the ceramic element comprises Al₂O₃, Si₃N₄, AlN, an HPSX ceramic (i.e., a ceramic with an Al₂O₃ matrix comprising an x-percent share of ZrO₂, for example Al₂O₃ with 9% ZrO₂=HPS9 or Al₂O₃ with 25% ZrO₂=HPS25), SiC, BeO, MgO, high-density MgO (>90% of the theoretical density), TSZ (tetragonally stabilized zirconium oxide) or ZTA as material for the ceramic. It is also conceivable that the ceramic element is designed as a composite or hybrid ceramics, in which several ceramic layers, which each differ in terms of their material composition, are arranged on top of one another and joined together to form an insulating layer in order to combine various desired properties. It is also conceivable that a metallic intermediate layer is arranged between two ceramic layers, which is preferably thicker than 1.5 mm and/or thicker than the two ceramic layers in total. Preferably, a ceramic that is as thermally conductive as possible is used for the lowest possible thermal resistance.

The skilled person understands a “DCB process” (direct copper bond technology) or a “DAB process” (direct aluminum bond technology) to be such a method, which serves, for example, to bond metal layers or sheets (e.g., copper sheets or foils or aluminum sheets or foils) to one another and/or to ceramics or ceramic layers, using metal or copper sheets or metal or copper foils which have a layer or coating (fusion layer) on their surface sides. In this method, described for example in U.S. Pat. No. 3,744,120 A or in DE23 19 854 C2, this layer or coating (fusion layer) forms a eutectic with a melting point below the melting point of metal (e.g., copper), so that by placing the foil on the ceramic and by heating all layers, these can be joined together, by melting the metal or copper essentially only in the region of the fusion layer or oxide layer.

In particular, the DCB process then has, for example, the following method steps:
Oxidizing a copper foil in such a way that a uniform copper oxide layer results;
Placing the copper foil on the ceramic layer;
Heating the composite to a process temperature between about 1025 to 1083° C., e.g., to about 1071° C.;
Cooling to ambient temperature.

An active solder process, e.g., for bonding metal layers or metal foils, in particular also copper layers or copper foils with ceramic material, is to be understood as a method which is specifically also used for producing metal-ceramic substrates, a bond is produced between a metal foil, for example copper foil, and a ceramic substrate, for example aluminum nitride ceramic, using a brazing solder which, in addition to a main component such as copper, silver and/or gold, also contains an active metal. This active metal, which is for example at least one element of the group Hf, Ti, Zr, Nb, Ce, establishes a bond between the brazing solder and the ceramic by a chemical reaction, while the bond between the brazing solder and the metal is a metallic brazing solder bond. Alternatively, a thick coating process is conceivable for bonding.

Hot isostatic pressing is known, for example, from EP 3 080 055 B1, the contents of which are hereby explicitly referred to with regard to hot isostatic pressing.

Preferably, it is provided that the structuring with the chemical process is terminated in particular after finishing the preparation step with the laser light. This ensures that a final removal is carried out exclusively with the etching agent, which in turn guarantees that the ceramic element is not damaged by the laser light.

In particular, it is intended that masking during etching is avoided in the production of the structuring. This is possible in particular because the structuring is specified by means of the removal by the laser light and an etching with an isotropic effect is used to cause a uniform removal on the entire upper surface of the at least one metal layer. Alternatively, it is also conceivable that masking is intended. It is also conceivable that in the preparatory step prior to etching, the recess is created having a depth smaller than the thickness of the at least one metal layer. For example, the recess already created can then be used to flow an etching agent only into this recess or to concentrate it here. For example, it is conceivable that an etching agent is applied and, as a result of tilting and pivoting movements on the upper surface of the at least one metal layer, excess etching agent either flows off the metal-ceramic substrate or flows into the recess.

Preferably, the chemical process, in particular the chemical process alone, is intended to cause removal of metal to expose a region of the outer surface of the ceramic element. In other words, the chemical process, which starts or continues after the end of the laser treatment, ensures that a residual amount of the metal layer is removed to form an isolation groove.

In principle, it is also conceivable that masking is intended at least in sections, for example to realize a stepped course or to maintain the thickness in the areas outside the planned isolation grooves. In this case, pre-structuring by means of the laser light, i.e., the formation of the recess during the preparatory step, also proves to be advantageous because it allows the masking to be applied more flexibly and in a simplified manner, for example by means of a corresponding printing process on the areas which have not undergone any removal of material during the preparatory step.

Furthermore, it is conceivable that masking is intended at least in sections, which is partially removed with laser light, wherein no material is removed from the upper surface of the at least one metal layer during etching. In this way, the original metal layer thickness can be retained at least in selected areas. In these areas, it is additionally conceivable to structure the at least one metal layer analogously to the further examples mentioned using laser light in combination with the etching process.

Preferably, it is intended that the chemical process and the laser process are carried out simultaneously, at least intermittently. This proves to be advantageous for the speed and duration required to realize the desired structuring and/or recess.

Preferably, the laser process is used to define, at least in sections, a geometry of a lateral surface of the at least one metal layer that is not parallel to the main extension plane. In particular, this relates to that lateral surface which bonds an upper edge of the at least one metal layer to a lower edge of the at least one metal layer. This lateral surface, which substantially laterally bounds the at least one metal layer, can thereby be suitably shaped in order to have a particularly advantageous effect on the thermal shock resistance. For example, it has been shown that the thermal shock resistance can be increased by forming a local maximum and/or a local minimum between the upper edge and the lower edge.

Preferably, the manufactured lateral surface runs diagonally and/or curved and/or stepped and/or segmented. By the corresponding geometric shape, additional positive properties for the metal-ceramic substrate can be induced, in particular with respect to the thermal shock resistance and the peelability of the at least one metal layer from the ceramic element. Furthermore, the heat spread can be taken into account in the formation of the corresponding geometry of the at least one metal layer or its lateral surface.

In particular, it is intended that a space between two mutually insulated and adjacent metal sections has an aspect ratio (height to width of the space) greater than 1, more preferably greater than 1.5 and most preferably greater than 2. This allows narrow isolation grooves to be provided, which permits a very compact arrangement of the metal sections, in particular even if the metal layer is comparatively thick, for example greater than 1.5 mm. In particular, the fact that material can be removed not only by isotropic etching (with which only a theoretical aspect ratio of at most 1 would be possible), but also by means of directional laser light, is exploited. This is what makes the corresponding aspect ratios possible in the first place.

Preferably, it is intended that an ultrashort pulse laser be used for the removal with laser light. The light used can be, for example, continuously emitted or pulsed light. Preferably, it is ultra-short pulse laser light with light pulses whose pulse length or pulse durations are shorter than a nanosecond. Preferably, the UKP laser is a laser source that provides light pulses with a pulse duration of 0.1 to 800 ps, more preferably 1 to 500 ps, most preferably 10 to 50 ps.

Preferably, it is intended that the realization of the structuring and/or recess, in particular within the scope of the preparatory or preparation step, is additionally supported by mechanical treating. For example, it is conceivable that a large-area removal of material of the at least one metal layer is carried out by means of a mechanical treating, for example a treating, in particular a milling, especially in such areas in which a predetermined breaking point is to be embedded in the later course, along which in turn, for example in a master card, a break is to be made between individual metal-ceramic substrates.

Preferably, it is intended that by means of the laser light a recess with a depth measured perpendicular to the main extension plane is produced, wherein a ratio of a maximum depth of the recess to a thickness of the at least one metal layer is a ratio between 0.7 and 0.99, preferably between 0.8 and 0.98 and more preferably between 0.9 and 0.95. By the maximum depth is particularly meant the largest depth to be determined, which is measured from an upper surface of the at least one metal layer in a direction perpendicular to the main extension plane. Insofar as the depth of the recesses is modulated, the maximum depth also means in particular its arithmetic means, which is determined, for example, by determining the depth of the recesses at a hundred different positions and then averaging them.

Preferably, it is intended that the at least one metal layer has a thickness that is greater than 1 mm, more preferably greater than 1.5 mm, and most preferably greater than 2.5 mm. Utilization or pre-structuring by means of the laser light proves to be advantageous in particular for such thick metal layers, because this allows particularly small distances between two adjacent metal sections to be realized, which would otherwise not be feasible if material were removed exclusively by means of an etching agent. This allows the printed circuit board to be designed in such a way that metal sections can be realized and formed on the upper surface of the ceramic element with the greatest possible economy of space.

Another object of the present invention is a method of making a metal-ceramic substrate comprising:
providing a ceramic element and at least one metal layer, wherein the ceramic element and the at least one metal layer extend along a main extension plane, and
bonding the ceramic element to the at least one metal layer to form a metal-ceramic substrate, in particular by means of a direct metal bonding process, hot isostatic pressing and/or a soldering process,
   wherein structuring, preferably for forming an isolation of metal sections, and/or a recess, preferably for forming a solder stop, is realized in the at least one metal layer by means of a mechanical process, for example milling or turning, and a chemical process, in particular etching. All advantages and properties described for the method for producing the metal-ceramic element using laser light apply analogously to the method for producing the metal-ceramic element using a mechanical process.

Preferably, it is intended that treating with the chemical process is terminated after finishing of the mechanical process and/or treating by means of the mechanical process is carried out as a preparatory step before or partially overlapping with the chemical process in terms of time. This makes it advantageously possible to avoid damaging the outside of the ceramic element during removal by a mechanical tool. Instead, a remaining metal residue is gently removed from the outside of the ceramic element in a material-friendly manner and the ceramic element is exposed again in certain areas. This serves to finally form the structuring or the desired isolation grooves between two adjacent metal sections.

A further object of the present invention is a metal-ceramic substrate produced by the method according to the invention. All of the properties and advantages described for the method can be transferred analogously to the metal-ceramic substrate and vice versa. In particular, the metal-ceramic substrate is a component of a power module and serves as a carrier for electrical or electronic components.

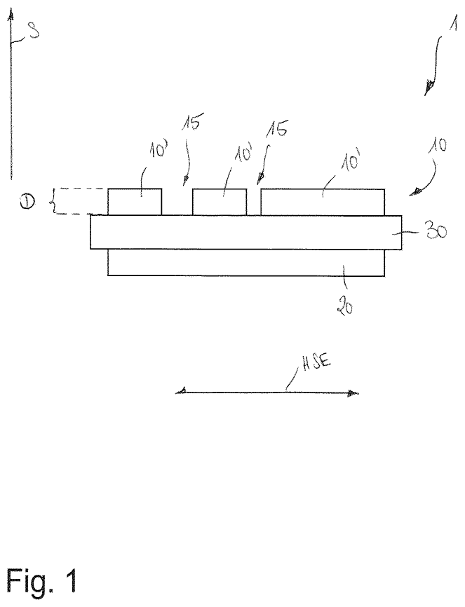

FIG. 1 schematically shows a metal-ceramic substrate 1 according to a first preferred embodiment of the present invention. Such a metal-ceramic substrate 1 is preferably a carrier for electrical components (not shown). In particular, it is intended that the metal-ceramic substrate 1 comprises a ceramic element 30 and at least one metal layer 10, wherein the ceramic element 30 and the at least one metal layer 10 extend along a main extension plane HSE. In this case, the at least one metal layer 10 is bonded to the ceramic element 30, wherein the at least one metal layer 10 and the ceramic element 30 are arranged one above the other in a stacking direction S extending perpendicular to the main extension plane HSE. In this context, it is particularly intended that the at least one metal layer 10 has a plurality of metal sections 10′, which are arranged, for example, electrically insulated from one another, next to one another along a direction running parallel to the main extension plane HSE.

Furthermore, it is most preferably intended that, viewed in stacking direction S, a backside metallization 20 is provided on the ceramic element 30 on the side opposite the at least one metal layer 10. The backside metallization 20 is intended in particular to counteract deformations which otherwise occur in operation and are caused by thermomechanical stresses which in turn are the consequence of different expansion coefficients in the at least one metal layer 10 and the ceramic element 30. At the same time, the backside metallization 20 is intended to provide sufficient heat capacity, which is particularly desired to provide an appropriate buffer in overload situations.

For the realization of a structuring 15, which for example separates two adjacent metal sections 10′ from each other, the prior art regularly intends to apply a masking or a resist layer to the bonded at least one metal layer 10 in order to remove, by means of an etching process, the areas in the at least one metal layer 10 which are not covered by a resist layer or the masking. Advantageously, this allows structuring 15 of the at least one metal layer 1, resulting in, for example, two metal sections 10′ of the at least one metal layer 10 being electrically insulated from each other. However, the application and production of the masking is costly and the consumption of the etching agent is comparatively large.

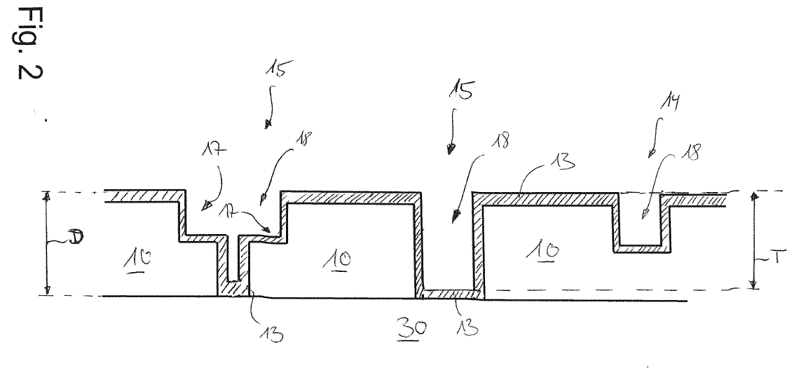

FIG. 2 schematically shows a sectional view through a metal-ceramic substrate 1, produced by a method according to an exemplary embodiment of the present invention. In particular, it is intended that for the production of a structuring 15, in particular for the formation of a space between two adjacent metal sections, i.e., for the formation of a so-called isolation groove, a removal of material in the at least one metal layer 10 is realized both by the use of laser light and by an etching.

Preferably, a recess 18 is first created in the at least one metal layer 10 in a preparatory step by means of the laser light, wherein the recess 18 has a maximum depth T that is smaller than the thickness D of the at least one metal layer 10. This ensures that no complete removal of material from the at least one metal layer 10 takes place during the treating of the at least one metal layer 10 with the laser light. This ensures that the laser light does not remove any components of the bonded ceramic element at the end of the treating of the at least one metal layer 10. In particular, it is intended here that a ratio of a maximum depth T of the recess to a thickness D of the at least one metal layer 10 has a ratio between 0.7 and 0.99, more preferably between 0.8 and 0.98, and most preferably between 0.9 and 0.95. In other words, a significant amount of material is removed from the at least one metal layer 10 by means of the laser light.

This can be, for example, a continuously operated cw laser or an ultrashort pulse laser, which is used to remove or ablate material of the at least one metal layer 10 in the preparatory step. Alternatively, it is also conceivable that in addition to the treating with the laser light, a mechanical treating is used to convince the recess 18 with that maximum depth T which is smaller than the thickness D of the at least one metal layer 10 in the scope of a preparatory step. This lends itself, for example, in such cases in which comparatively large areas are to be exposed, for example in such areas in which later predetermined breaking points are let in, along which, for example in the case of a master card, the metal-ceramic substrate is separated into several individual metal-ceramic substrates.

Following the preparatory step in which the recess 18 with the maximum depth T, which is smaller than the thickness D of the at least one metal layer 10, is created, a removal of the material of the at least one metal layer 10 is carried out by means of an etching process. In particular, it is intended that remaining parts 13 of the at least one metal layer 10, which are left after the material of the at least one metal layer 10 has been removed by means of the laser light and are removed by means of the etching process, are removed by means of the etching process. In other words, by using the etching process, the removal of the remaining parts 13 necessary for the isolation of adjacent metal sections 10′ is carried out, for example in the area of the planned isolation groove. In this case, the remaining parts 13 also extend, for example, over the metal sections 13 which are to be retained on the manufactured metal-ceramic substrate 1 after the structuring or the recess has been formed.

In this context, it is more preferably intended that masking or a resist layer is forgone during the etching process or the etching step. This results in a uniform removal of material, in particular on the at least one metal layer 10, preferably on the side facing away from the ceramic element 30. Due to the profile or contour of the recess 18 predetermined by the laser light with the maximum depth T, which is smaller than the thickness D of the at least one metal layer 10, this leads to the fact that in particular in the area of this recess 18 the remaining part 13 of the material of the at least one metal layer 10 can be removed in order to realize an electrical isolation of two adjacent metal sections 10′ in the at least one metal layer 10. Therefore, with the described procedure, it is advantageously possible to forgo a costly masking or formation of a resist layer on the upper surface of the at least one metal layer 10. In addition, etching agents can be advantageously saved and the method can preferably also be accelerated, since the etching process is now intended only for a minor or smaller removal of material, in particular to ensure that no damage occurs to the ceramic element 30 during production by means of laser light and/or mechanical process. The acceleration of the method also results, in particular, if the formation of a masking or a resist layer is forgone, which predetermines the position of the structuring 15.

Preferably, it is intended in this case that a geometry of a lateral surface 17, which does not run parallel to the main extension plane, of the at least one metal layer 10 is determined at least in sections by means of the laser light. In this way, it is advantageously possible to use the laser light to specify how an outer region of the at least one metal layer 10 or of the metal sections 10′ is configured. This is advantageous in particular because it has proven to be advantageous to realize geometries in the lateral surface 17 which are determined for thermal shock resistance and which bond an upper edge of the at least one metal layer 10 to a lower edge of the at least one metal layer 10, wherein the lower edge limits the at least one metal layer on that side which faces the ceramic element 30, while the upper edge limits the metal layer 10 on that side which faces away from the ceramic element 30.

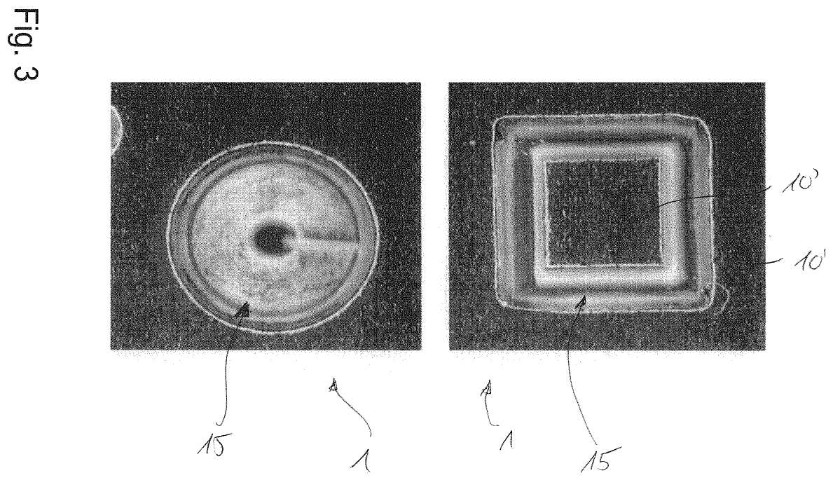

FIG. 3 shows top views of two different manufactured metal-ceramic substrates 1, wherein the manufactured metal-ceramic substrates 1 were manufactured using an exemplary method for manufacturing the metal-ceramic substrate 1 according to the present invention. In particular, the upper embodiment in FIG. 3 shows an island-like square metal section 10′, while in the lower embodiment a substantially circular space for structuring 15 is realized in the at least one metal layer 10.

### REFERENCE NUMERALS

1 Metal-ceramic substrate
10 Metal layer
10′ Metal section
13 Remaining parts
14 Recess
15 Structuring
17 Lateral surface
18 Recess
20 Backside metallization
30 Ceramic element
S Stacking direction
D Thickness
T Depth
HSE Main extension plane

1. A method of manufacturing a metal-ceramic substrate (1), comprising:
providing a ceramic element (30) and at least one metal layer (10), wherein the ceramic element (30) and the at least one metal layer (10) extend along a main extension plane (HSE); and
bonding the ceramic element (30) to the at least one metal layer (10) to form a metal-ceramic substrate (1) is realized in the at least one metal layer (10) by means of a laser process and a chemical process.

2. The method of claim 1, wherein treating with the chemical process is terminated after finishing the laser process.

3. The method according to claim 1, wherein treating by means of the laser process is carried out as a preparatory step in time before the chemical process.

4. The method according to claim 1, wherein by the chemical process, a removal of metal is effected, with which a region of the outer side of the ceramic element (30) is exposed.

5. The method according to claim 1, wherein the chemical process and the laser process are carried out simultaneously at least intermittently.

6. The method according to claim 1, wherein a geometry of a lateral surface (17) of the at least one metal layer (10) that is not parallel to the main extension plane (HSE) is determined at least in sections by means of the laser process.

7. The method according to claim 6, wherein the manufactured lateral surface (17) is diagonal and/or curved and/or stepped and/or segmented.

8. The method according to claim 1, wherein a space between two mutually insulated and adjacent metal sections has an aspect ratio greater than 1.

9. The method according to claim 1, wherein an ultrashort pulse laser is used in the laser process.

10. The method according to claim 1, wherein the formation of the structuring (15) and/or recess (14) is additionally supported by mechanical treating.

11. The method according to claim 1, wherein a recess (18) having a depth (T) dimensioned perpendicular to the main extension plane (HSE) is produced by means of laser light, wherein a ratio of a maximum depth (T) of the recess (18) to a thickness (D) of the at least one metal layer (10) has a ratio between 0.7 and 0.99.

12. The method according to claim 1, wherein the at least one metal layer (10) has a thickness (D) that is greater than 1 mm.

13. The method of manufacturing a metal-ceramic substrate (1), comprising:
providing a ceramic element (30) and at least one metal layer (10), wherein the ceramic element (30) and the at least one metal layer (10) extend along a main extension plane (HSE); and
bonding the ceramic element (30) to the at least one metal layer (10) to form a metal-ceramic substrate (1),
wherein a structuring (15) is realized in the at least one metal layer (10) by means of a mechanical method, for example a milling, and a chemical process.

14. The method according to claim 13, wherein treating with the chemical process is terminated after finishing of the mechanical process and/or treating by means of the mechanical process is carried out as a preparatory step temporally before the chemical process.

15. The metal-ceramic substrate (1) produced by a method according to claim 1.
